(19) United States
(12) Patent Application Publication
(10) Pub. No.: US 2026/0347635 A1
(43) Pub. Date: Nov. 5, 2026

(54) CONFORMAL THERMOCOUPLE USING PARTICLE-FREE INK MATERIALS

(71) Applicant: The Research Foundation for The State University of New York, Amherst, NY (US)

(72) Inventor: Shenqiang REN, Williamsville, NY (US)

(21) Appl. No.: 19/146,118

(22) PCT Filed: Jan. 5, 2024
(86) PCT No.: PCT/US2024/010588

§ 371 Date: Jul. 7, 2025

Related U.S. Application Data
(60) Provisional application No. 63/478,691, filed on Jan. 5, 2023.

(51) Int. Cl. C09D 11/52; C09D 11/38; G01K 7/02; H10N 10/13

(52) U.S. Cl. CPC C09D 11/52; C09D 11/38; G01K 7/028; H10N 10/13

(57) ABSTRACT

Thermocouples and methods and systems for making thermocouples are disclosed. A method of making a thermocouple includes depositing a first metal-organic decomposition (MOD) ink onto a substrate. A second MOD ink is deposited onto the substrate. The first and second MOD inks are sintered thereby forming a first element and a second element, respectively. A thermocouple junction is formed by contact of the first element and the second element (which may be direct or indirect via a coupler). For example, the first element may have a first Seebeck coefficient and the second element may have a second Seebeck coefficient selected to form a thermocouple junction with the first element.

### CROSS-REFERENCE TO RELATED APPLICATIONS

This application claims priority to U.S. Provisional Application No. 63/478,691, filed on Jan. 5, 2023, now pending, the disclosure of which is incorporated herein by reference.

### STATEMENT REGARDING FEDERALLY SPONSORED RESEARCH

This invention was made with government support under grant no. W911NF-20-2-0016 awarded by the DEVCOM Army Research Laboratory. The government has certain rights in the invention.

### FIELD OF THE DISCLOSURE

The present disclosure relates to flexible electronic sensors, and more particularly to printable thermocouples.

### BACKGROUND OF THE DISCLOSURE

Printed hybrid electronic devices are becoming lighter and smaller, and in many cases, flexible. One device of interest is the temperature sensor, which includes the likes of resistance temperature detectors (RTDs), thermistors, semiconductor-based integrated circuits, and thermocouples. In this context, thermocouples have been of interest due to a variety of material selections although traditional thermocouples would be made of bulk metals. There is a need for smaller, flexible thermocouples and technologies for making them.

### BRIEF SUMMARY OF THE DISCLOSURE

The present disclosure provides embodiments of flexible and conformal thermocouples which can be made by printing liquid metal-organic decomposition materials, having, for example, Cu and CuNi particle-free conductive inks. Fine prints were observed when printed and fully converted and conductive prints were obtained once sintered. An exemplary printed Cu—CuNi (type-T) thermocouple according to an embodiment of the present disclosure demonstrated a linear temperature response with the sensitivity of 20.6 μV/°C and a response time below 2 seconds. In addition, embodiments of the presently disclosed printed flexible thermocouple sensor exhibited a high stability and reliability when subjected to external stimuli such as bending, humidity, and thermal cycling. Printed conformal thermocouples using liquid metal decomposition ink materials provide a promising avenue towards miniaturized hybrid electronic devices.

### DESCRIPTION OF THE DRAWINGS

For a fuller understanding of the nature and objects of the disclosure, reference should be made to the following detailed description taken in conjunction with the accompanying drawings, in which:

FIG. 1A. Illustration of printing with inkjet printing. The images show containers of Cu and CuNi metal-organic decomposition (MOD) inks before printing. The molecule is the general form of the metal complex within each ink. The optical images at the bottom of the figure correspond to the deposited lines before and after sintering (the scalebar corresponds to 500 μm).

FIG. 1B. Thermogravimetric analysis (TGA) of Cu and CuNi MODs.

FIG. 1C. Powder x-ray diffraction (pXRD) diffractogram of the Cu and CuNi MODs. The dashed lines represent copper and nickel peaks.

FIG. 2A. Scanning electron microscope (SEM) images of Cu MOD sintered at 100, 150, 200 °C (left-to-right, the scalebars correspond to 5 μm).

FIG. 2B. SEM images of CuNi MOD sintered at 200, 250, and 300 °C (left-to-right, the scalebars correspond to 5 μm).

FIG. 2C. An overlaid energy-dispersed x-ray spectroscopy (EDS) spectra of copper (top) and nickel (bottom) for the Cu and CuNi samples (the scalebars represent 100 μm).

FIG. 2D. A sintering profile of Cu and CuNi MOD samples at varying sintering temperatures.

FIG. 2E. A sintering profile of Cu and CuNi MOD samples at varying sintering times.

FIG. 3A. Testing the stability of Cu and CuNi MOD samples through mechanical testing showing resistance curve (the (o) and (x) represent bending and relaxed, respectively).

FIG. 3B. IV curves of Cu and CuNi MOD samples in flat and bent configurations.

FIG. 3C. Results of humidity testing Cu and CuNi MOD samples.

FIG. 3D. Results of aging testing Cu and CuNi MOD samples at 50 and 100 °C.

FIG. 4A. Sensitivity curve of example thermocouples based on their voltage at 30 °C.

FIG. 4B. Heating response of a sample thermocouple compared with a reference type “T” thermocouple.

FIG. 4C. Response test of a sample thermocouple using ice.

FIG. 4D. Response test of a sample thermocouple using body heat (grasping between fingers) for 10 cycles. The inset is a zoomed in graph of one of the cycles.

FIG. 4E. Stability test of a sample thermocouple at control and when contoured to a hand. The inset images include dark annotation lines to make it easier to see the thermocouple location.

FIG. 4F. Testing a sample thermocouple on a finger. Each vertical line represents a change to a different position.

FIG. 5. Inkjet printing based on substrate temperature.

FIG. 6. SEM images of Cu MOD sintered at 125 °C (top) and 175 °C (bottom).

FIG. 7. An SEM image of CuNi sintered at 150 °C.

FIG. 8. Images of printing (left), sintering (middle), and finishing the preparation of the thermocouple (right).

FIG. 9A. Plot depicting the average height of the example Cu inkjet print.

FIG. 9B. Plot depicting the average height of the example CuNi inkjet print.

FIG. 10. Adhesion testing of inkjet prints on flexible substrate. (a) CuNi. (b) Cu.

FIG. 11. End-to-end bending of Cu and CuNi samples. CuNi samples were stable, but Cu samples showed slow degradation after each cycle.

FIG. 12. Several temperature calibration curves for different thermocouples with different starting resistances.

FIG. 13. Testing the response time of a thermocouple according to an embodiment of the present disclosure based on four different intensities on a solar simulator.

FIG. 14. A thermocouple according to an embodiment of the present disclosure.

FIG. 15. A chart depicting a method according to another embodiment of the present disclosure.

### DETAILED DESCRIPTION OF THE DISCLOSURE

Printed hybrid electronic devices are quickly progressing toward lightweight and compact whilst also being flexible. One device of interest is the temperature sensor, which includes the likes of resistance temperature detectors (RTDs), thermistors, semiconductor-based integrated circuits, and thermocouples. In this context, thermocouples have been of interest due to a variety of material selections although traditional thermocouples would be made of bulk metals. Thermocouples function on the Seebeck effect, a phenomenon which causes a small thermoelectric current to be produced when a junction made up of two different metallic materials in contact is subjected to varying temperatures. As the other end of the thermocouple (the nonjunction end) is open, a contact electromotive force is produced, which is proportional to the temperature difference between the junction and nonjunction ends of the thermocouple. A transition to thin and compact thermocouples requires the use of printable inks with relatively lower energy needs. However, most printable metallic inks are prone to oxidation during storage and manufacturing. Potential printable inks that address these challenges are metal-organic decomposition (MOD) inks. They provide unique advantages over traditional printable inks like oxidation prevention due to the use of metal ions and solubility of complexes in solvents and can be reduced from low temperatures. This allows plastics to be used as substrates, thereby allowing flexible devices. Additionally, these inks are suitable for jet printing because of their low viscosity and lack of solid particles. When utilized with an inkjet printer (i.e., inkjet printhead), significantly finer features are possible as compared with other printing methods.

Copper-copper/nickel (Cu—CuNi) is a type T thermocouple material that has been employed to measure temperatures in the range of −200 to 200 °C. It has also been shown that the thermoelectric properties and linear characteristics of the Cu—CuNi thermocouple are of adequate standard, displaying high sensitivity and stability.

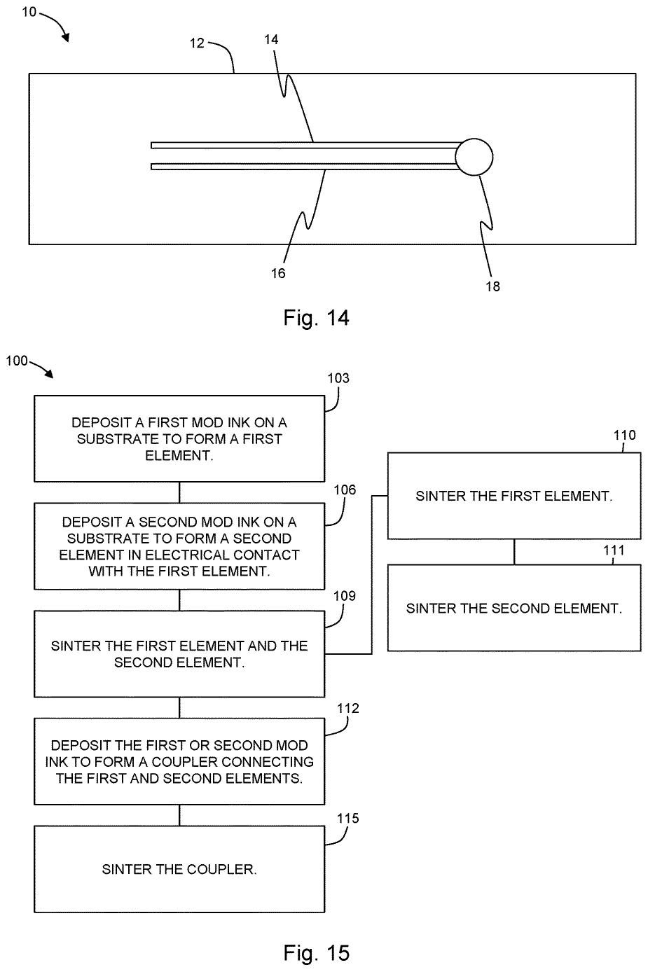

The present disclosure provides embodiments of inkjet-printed conformal thermocouples utilizing MOD inks—for example, using liquid Cu and CuNi MOD inks—and methods for making such thermocouples. With reference to FIG. 14, in an embodiment, a thermocouple 10 includes a substrate 12. The substrate may be a plastic. The substrate may be, for example, polyethylene terephthalate (PET), polyimide (such as polyimide film—Kapton), or other such material. The substrate may be a woven or non-woven fabric. The substrate may be an electrical insulator. A first element 14 is disposed (e.g., printed) on the substrate. The first element is a first metal-organic decomposition ink. For example, the first element is a metallic component formed from a first metal-organic decomposition ink. The first metal-organic decomposition ink may include, for example, a copper complex. For example, the copper complex may have an ionic copper center with two formate ligands and two amine ligands. The first element may have a thickness of between 250 nm and 4 μm, inclusive. In some embodiments, the thickness may be more or less than this range. In a particular example, the thickness of the first element is 2 μm.

A second element 16 is disposed (e.g., printed) on the substrate 12. The second element is a second metal-organic decomposition ink. The second decomposition ink is selected such that the second element and the first element form a thermocouple junction. For example, the Seebeck coefficient of the first element may be sufficiently different from the Seebeck coefficient of the second element to produce a thermocouple effect. For example, the second element is a metallic component formed from a second metal-organic decomposition ink. The second metal-organic decomposition ink may include, for example, a copper complex and a nickel complex. For example, the copper complex of the second metal-organic decomposition ink may have an ionic copper center with two formate ligands and two amine ligands, and the nickel complex may have an ionic nickel center with two formate ligands and two amine ligands. The first element may have a thickness of between 250 nm and 4 μm, inclusive. In some embodiments, the thickness may be more or less than this range. In a particular example, the thickness of the first element is 2 μm. In some embodiments, at least a portion of the second element overlaps the first element (or vice versa). In such embodiments, the total thickness of the overlapping elements may have a thickness of between 250 nm and 4 μm, inclusive. In some embodiments, the thickness of the overlapping elements may be more or less than this range. In a particular example, the thickness of the overlapping elements is 2 μm.

The first element and second element may be in direct or indirect electrical contact. For example, in some embodiments, the first element 14 is spaced apart from the second element 16 and a coupler 18 connects the first element and the second element. The coupler may be formed from the first metal organic decomposition ink or the second metal organic decomposition ink.

In another aspect, a thermocouple 10 may have a first element 14 having sintered copper particles formed using a first metal organic decomposition ink and a second element 16 having sintered copper-nickel particles formed using a second metal organic decomposition ink. The metal organic decomposition inks may be selected such that the resulting first element has a Seebeck coefficient which is sufficiently different from the Seebeck coefficient of the second element such that the first and second elements produce a thermocouple effect.

With reference to FIG. 15, in another aspect, a method 100 of making a thermocouple includes depositing 103 a first metal-organic decomposition ink on a substrate to form a first element. The substrate may be as described elsewhere in this disclosure. The first metal-organic decomposition ink may be as described elsewhere in this disclosure. For example, the first metal-organic decomposition ink may include a copper complex. The copper complex may have, for example, an ionic copper center with two formate ligands and two amine ligands. A second metal-organic decomposition ink is deposited 106 on the substrate to form a second element in electrical contact with the first element. The second metal-organic decomposition ink may be as described elsewhere in this disclosure. For example, the second metal-organic decomposition ink may include, for example, a copper complex and a nickel complex. For example, the copper complex of the second metal-organic decomposition ink may have an ionic copper center with two formate ligands and two amine ligands, and the nickel complex may have an ionic nickel center with two formate ligands and two amine ligands.

The first and second elements are sintered 109 (i.e., the first element is sintered 110, and the second element is sintered 111). The sintering may happen simultaneously—for example, the first MOD ink may be deposited and the second MOD ink may be deposited and then both deposited inks are sintered. In other embodiments, the sintering steps may happen separately. For example, the first MOD ink may be deposited and sintered, and then the second MOD ink may be deposited and sintered. In this way, the inks may be sintered using different characteristics (e.g., sintering temperatures, sintering times, sintering environments, etc.) Once sintered, a thermocouple junction is formed by the first element and the second element.

The sintering 110,111 may be performed at a sintering temperature of between 100 °C and 400 °C, inclusive. In some embodiments, the sintering temperature(s) may be more or less than this range. The sintering 110,111 may be performed for a sintering time of between 1 minute and 1 hour, inclusive. In some embodiments, the sintering time may be more or less than this range. For example, choice of first and/or second metal-organic material may necessitate temperature or time that may be higher than, lower than, a subset of, a superset of, or overlapping with these exemplary ranges. In some embodiments, sintering the second element causes a copper-nickel alloy to form in at least a portion of the second element. The first element and the second element may be sintered at the same time or separately from each other. For example, where one of the first element or the second element has a higher sintering temperature, such element may be sintered first, and then the other element may be deposited on the substrate and subsequently sintered.

The first element and second element may be in direct or indirect electrical contact. For example, in some embodiments, the first element is spaced apart from the second element and a coupler is formed to connect the first element and the second element. In an example of a method, the second metal-organic decomposition ink may be deposited 112 on the substrate to form a coupler connecting the first element to the second element, and the coupler is sintered 115. The first MOD ink and the second MOD ink may be deposited such that they are spaced apart with a portion of each in contact with the other (to form the thermocouple junction). In other embodiments, the first MOD ink and the second MOD ink are deposited such that they are spaced apart and are connected by depositing a coupler.

In some embodiments, the first and second elements are covered, for example, after sintering. For example, the fabricated thermocouple may be covered using Kapton tape.

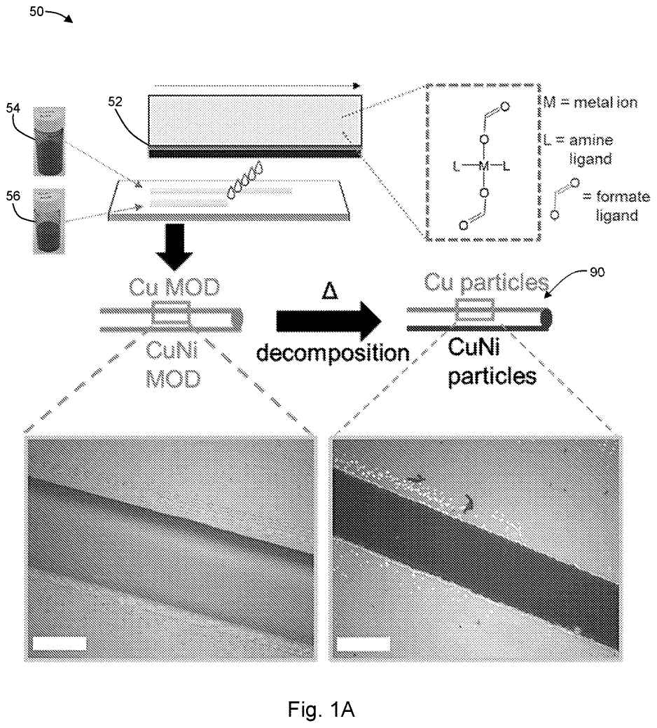

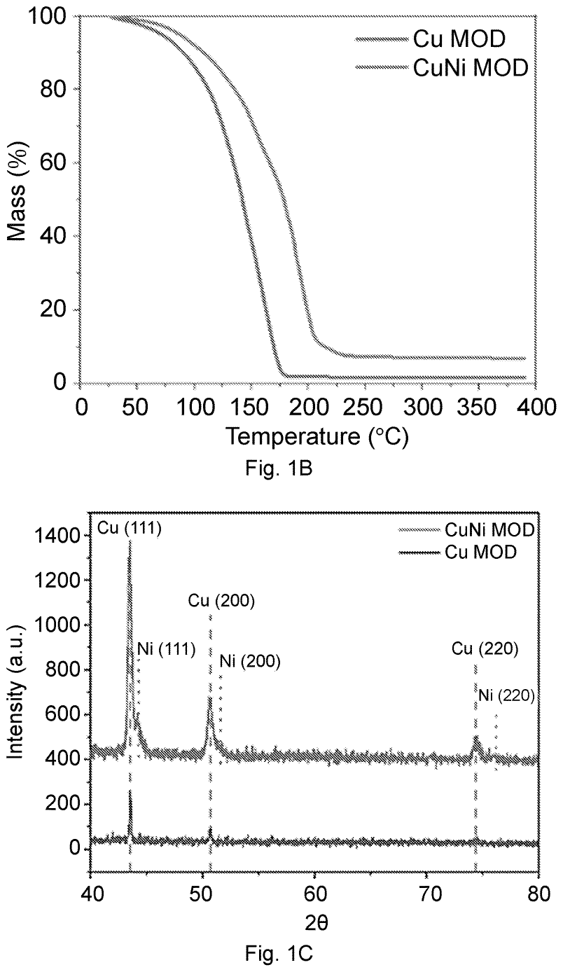

In another aspect, the present disclosure may be embodied as a system 50 for fabricating a thermocouple 90 (see FIG. 1A). The system 50 includes an inkjet printhead 52. A first metal-organic decomposition ink 54 is in fluid communication with the inkjet printhead. For example, the first MOD ink 54 may be contained in a reservoir which is fluidically connected to the inkjet printhead such that the printhead may deposit the first MOD ink. A second MOD ink 56 is in fluid communication with the inkjet printhead. For example, the second MOD ink 56 may be contained in a reservoir which is fluidically connected to the inkjet printhead such that the printhead may deposit the first MOD ink. In some embodiments, the printhead may be configured to print using the MOD inks sequentially (e.g., through the same or different orifices of the printhead). In some embodiments, the printhead may be configured to print using the MOD inks simultaneously (e.g., through separate orifices of the printhead). In some embodiments, the system may include a sintering oven.

### Experimental Embodiment

The following describes exemplary embodiments used to prototype and characterize thermocouples according to embodiments of the present disclosure, and not intended to be limiting.

In an experimental embodiment, an inkjet-printed flexible type T thermocouple was fabricated utilizing two different MOD inks-liquid copper (Cu) and copper/nickel (CuNi) MOD materials. The MOD inks were selected to print the fine lines of conductive Cu and CuNi features.

### Preparation and Printing of Example Cu(Ni) MOD Ink

A MOD ink was prepared first and diluted to make inkjet printable ink. To make Cu MOD, copper formate (Cu—F) was mixed with 2-amino-2-methylpropanol (AMP) and tetramethylethylenediamine (TMEDA) at a 1:1:1 molar ratio. This was mixed until a viscous liquid was acquired. Extensive studies on Cu MOD has been done in one of our recent works (Sheng, A.; Islam, A.; Khuje, S.; Yu, J.; Tsang, H.; Bujanda, A.; Ren, S., Molecular copper decomposition ink for printable electronics, Chem. Commun. 2022, 58, 9484-9487, which is incorporated herein by this reference). To make CuNi MOD, Cu—F was first mixed with AMP at a 1:2 molar ratio. Separately, nickel formate (Ni—F) was mixed with 1-amino-2-propanol (AMIP) ligand at a 1:2 molar ratio. Each was mixed until a viscous liquid was achieved. Cu and Ni MODs were then mixed together at a 1:1 Cu:Ni molar ratio (e.g., 3.14 g of Cu—F-AMP MOD and 2.6 g Ni—F-AMIP) to make CuNi MOD. A medium was used to dilute the viscous inks before use with an inkjet printer. This medium was prepared by mixing ethylene glycol, 2-methoxyethanol, and methanol together at a weight ratio of 7:2:1. The final inkjet printable ink was a mixture of one part ink and two parts of the medium. The above materials and methods are exemplary and not intended to be limiting.

The samples were printed using a FUJIFILM Dimatix printer DMP-2800. The inks were filtered into a Dimatix Materials Cartridge before printing. The cartridge temperature was set to 50 °C, whereas the print bed was kept at 60 °C. The substrate dimensions were 3.3 cm×1 cm, the thermocouple dimensions were 2 cm long×0.3 cm wide (the junction) with an average thickness of 2 μm, and the width of each printed feature was between 600 and 700 μm.

### Sintering and Characterization of the Example Printed MOD Samples and Thermocouples

The samples were sintered in a tube furnace under an inert atmosphere at various temperatures (ranging from 100 to 300 °C) and times (from 1 to 60 min). Electrical conductivities were obtained via an Oscilla four-point probe. The stability measurements were measured using a Keithley.

The thermocouple was sintered similarly to the individual MOD samples with an additional step. After the first line was printed, the next ink to print was offset to create two lines which were close together. These lines were sintered first to provide conductive prints. To form the thermocouple, these lines were connected using a drop of CuNi MOD ink that was promptly sintered. The conditions used for sintering were 300 °C for 30 min under an inert atmosphere. A Keithley was used to measure the voltage data from the thermocouple. An Atkins thermocouple probe (Bare tip, 39138-T) was used for calibration purposes.

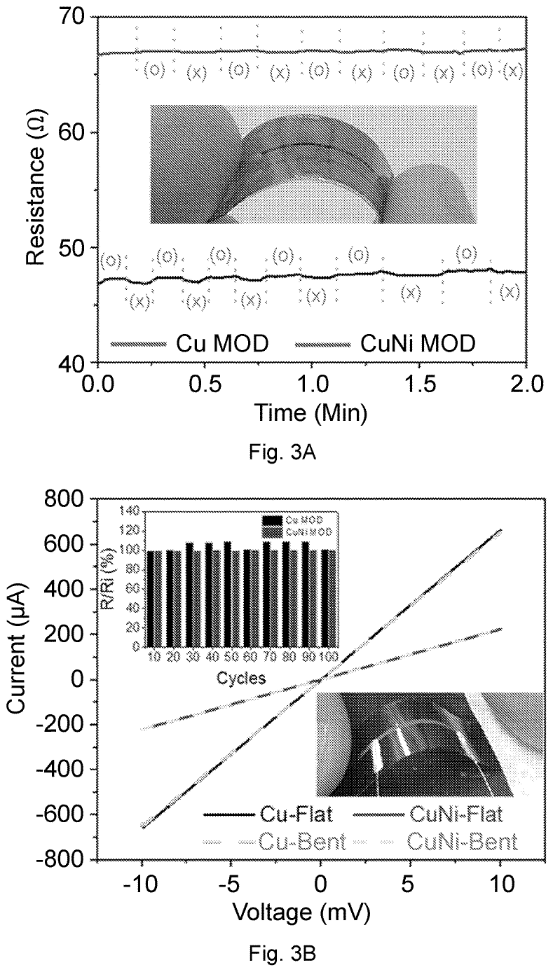

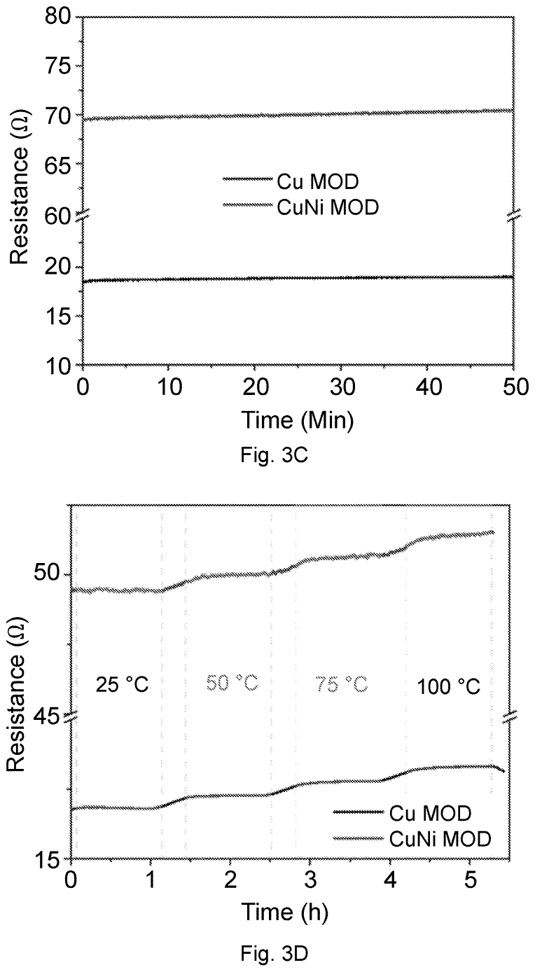

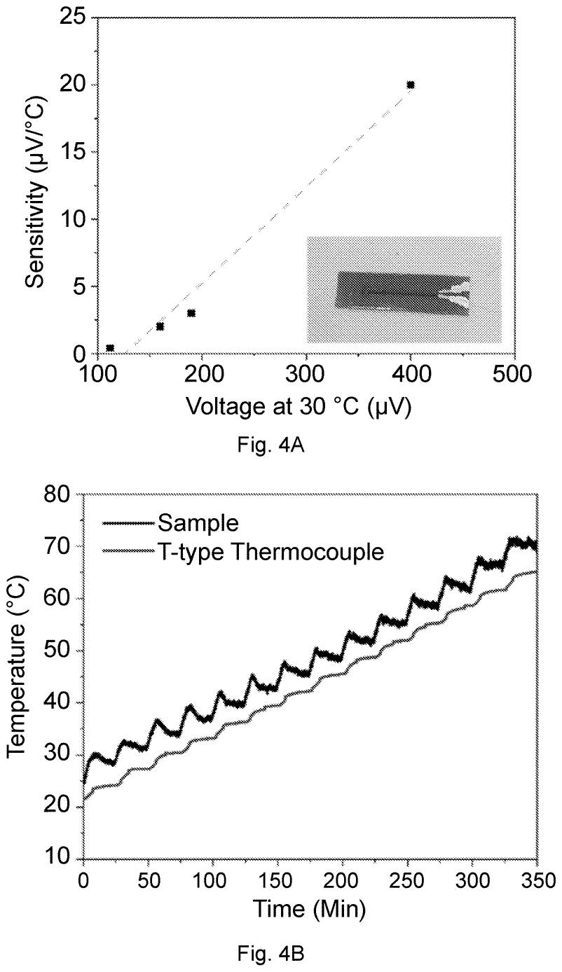

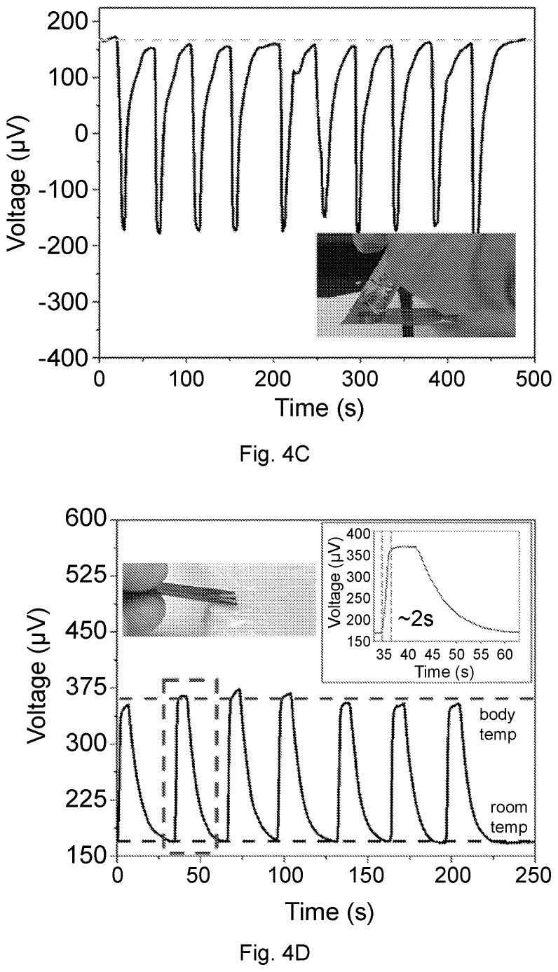

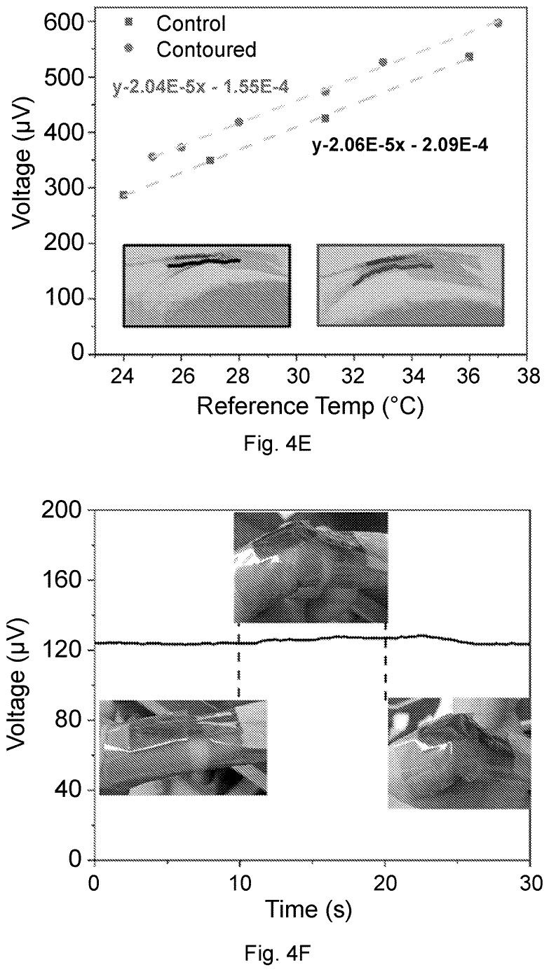

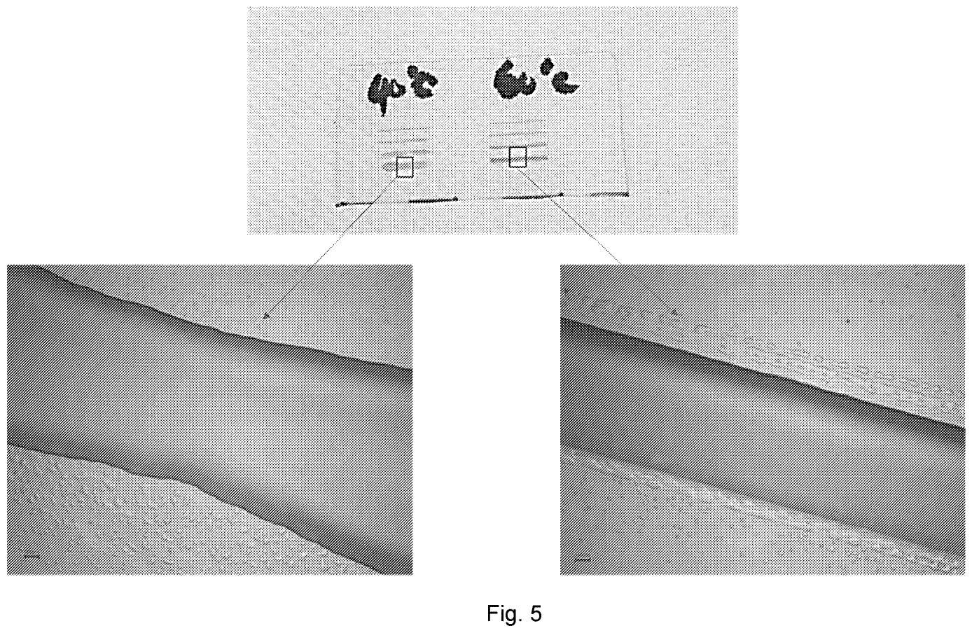

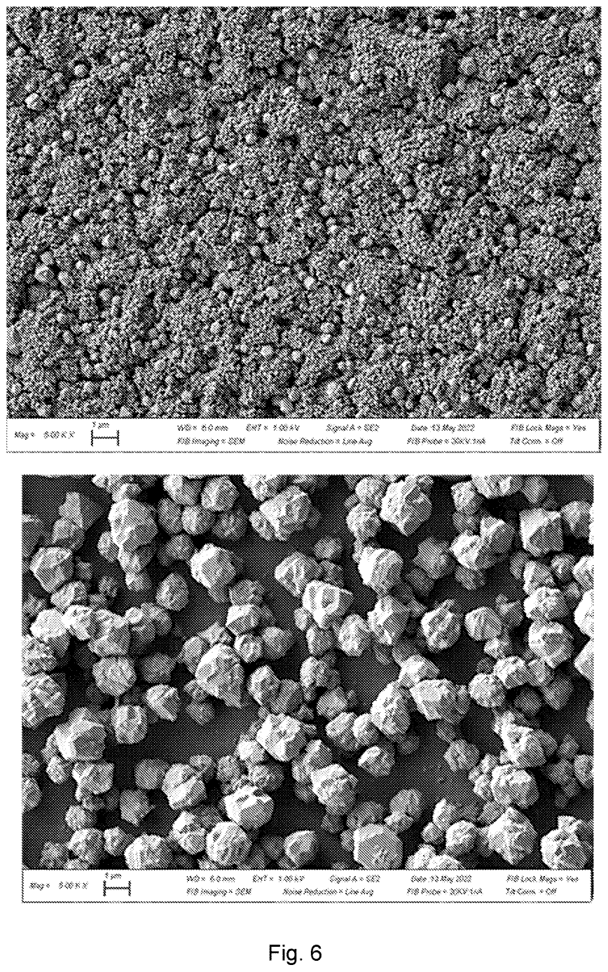

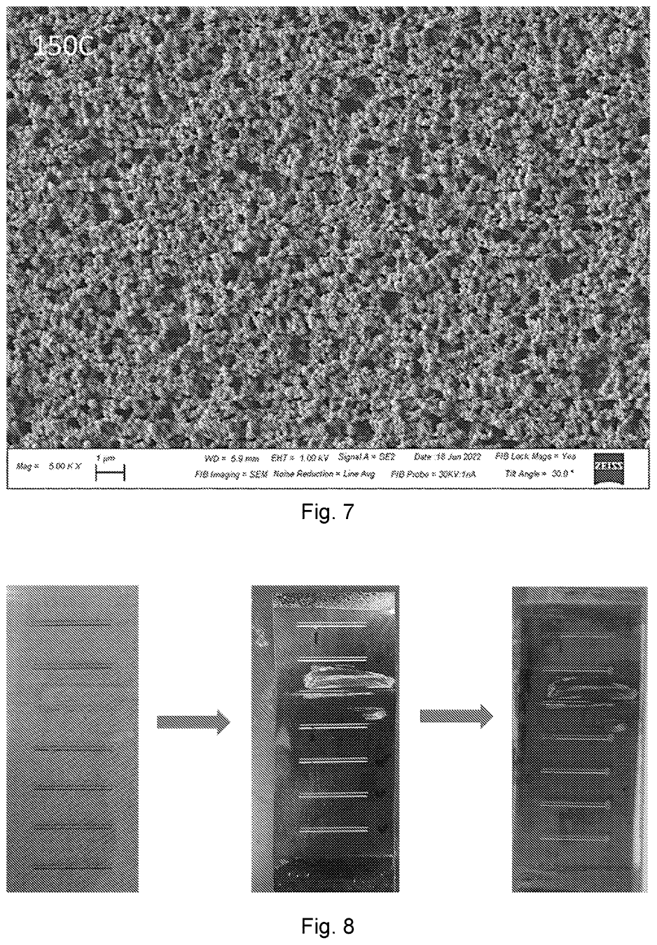

Once sintered, the printed Cu conductor was shown to have particles of an average diameter of 1 μm with an electric conductivity up to 900 kS/m. The CuNi conductor possessed smaller particles (with the average diameter of 100 nm) with an electric conductivity of 100 kS/m when compared to the printed Cu conductor. Powder X-ray diffraction (pXRD) and energy-dispersed X-ray spectroscopy (EDS) confirmed the formation of CuNi alloys. These two conductors were evaluated for stability with the printed CuNi conductor showing superior stability relative to the Cu conductor in the mechanical testing, humidity testing, and aging in elevated temperatures (see FIGS. 3A-3D). The printed flexible type T thermocouple was observed to have a linear increase in resistance as a function of temperature and was able to detect small changes in temperature with the sensitivity as high as 20.6 μV/°C and a response time below 2 s (FIGS. 4A-4F).

The illustration of FIG. 1A shows how an inkjet cartridge jets the ink from the nozzles when printing the Cu—CuNi thermocouples. Each line represents a different MOD ink used (CuMODor CuNi MOD; pictures of the inks are shown). Both ink complexes can be described similarly, with a metal ion in the center (M), two formate ligands, and two amine ligands (L). The images of the thermocouple after printing and sintering are shown as well. The printed features have a width of around 500 μm with both MOD inks displaying similar colors. Once sintered, a clear change was observed—the Cu MOD turned into copper particles with a pinkish color, whereas the CuNi MOD converted into CuNi particles with a dark color. Thermogravimetric analysis (TGA) of the two MOD inks is shown in FIG. 1B. For liquid Cu MOD ink, there was a steady decrease in mass starting around 125 °C. The CuNi MOD, on the other hand, had a steady decrease in mass, which started around 150 °C. This increase in decomposition temperature can be attributed to the Ni complex needing higher temperatures for decomposition. However, the temperature of decomposition was lower than the normal NiF-based complex, so the improvement in decomposition is also attributed to the formation of Cu seeds that facilitate the growth of Ni at lower temperatures. pXRD diffractograms for the sintered Cu and CuNi samples were collected (FIG. 1C). In the liquid Cu MOD sample, the expected peaks corresponding to Cu were present (111, 200, and 220 peaks at 43.4, 50.5, and 74.2 °C, respectively). For the sintered CuNi feature, the extra peaks lie in between Cu and Ni peaks, strongly suggesting that a CuNi alloyed phase was present within the sample. This observation provides evidence that both MOD inks formed metallic traces.

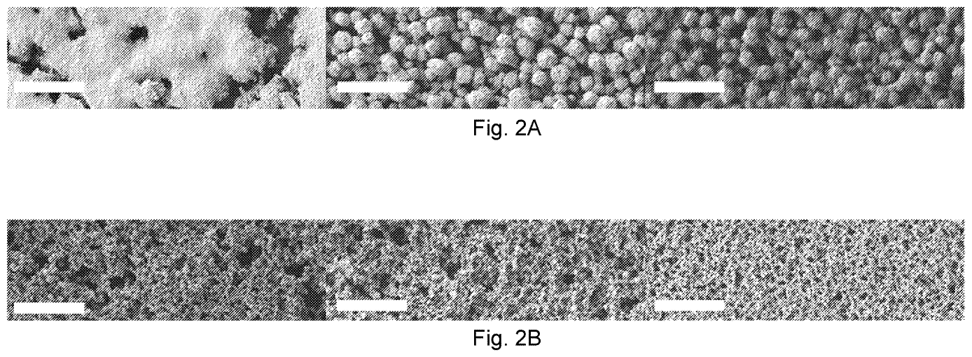

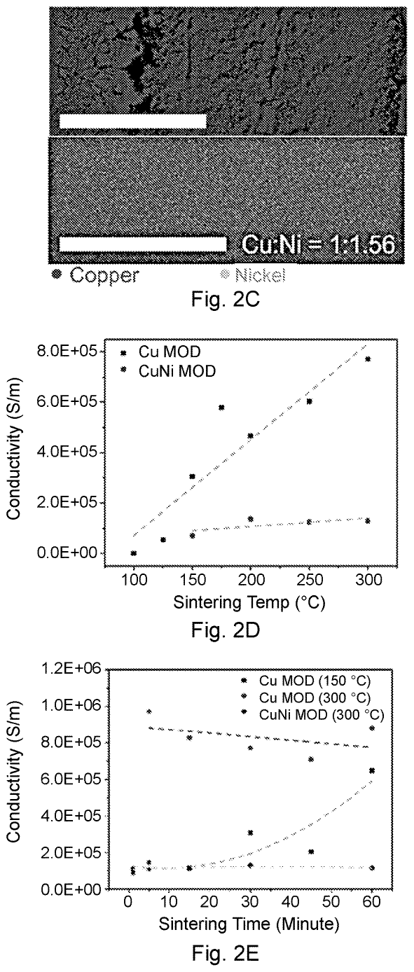

The individual MOD inks were further characterized for their sintering-based properties. SEM images for sintered Cu and CuNi are shown in FIGS. 2A and 2B, respectively. First, when liquid Cu MOD was sintered at 100 °C, there were no clearly observed particles. Starting from 150 °C and higher, Cu nanoparticles started to form with sizes around 1 μm for 150 and 200 °C. At 200 °C, some particles were observed for sintered CuNi MOD. When compared to Cu particles, the CuNi particles were significantly smaller with sizes around 100 nm. These observations agree with the TGA results described above. An EDS spectrum was collected for Cu (top) and CuNi (bottom) samples (FIG. 2C). Unsurprisingly, the EDS spectra of the Cu sample showed strong and clear signal for only copper. On the other hand, it was observed for the CuNi sample that once overlapped, it possessed both Cu and Ni signals, which were dispersed and mixed throughout the sample. Additionally, from the EDS spectra, it was determined that the concentration of Cu to Ni was 1:1.56. The corresponding Cu and CuNi samples were then tested for their conductivities as a function of sintering temperature (FIG. 2D) and time (FIG. 2E). With increasing sintering temperature, there was a clear and significant increase in electric conductivity measured for Cu (from 0 to 800 kS/m).

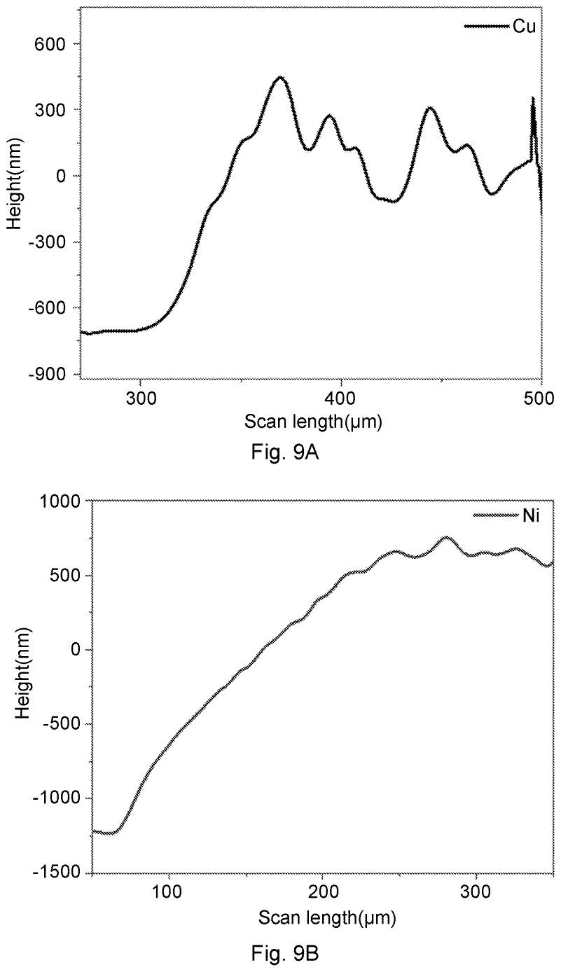

This was seen to a significantly lesser extent for CuNi, where the conductivity values were around 100 kS/m at all temperatures. The increased conductivity that was observed for Cu MOD can be explained with better percolation at increasing temperatures. However, the conductivity of CuNi was potentially affected due to the presence of the Ni phase. This observation can be due to the Ni nucleation during heating. This would interrupt the growth of Cu, which effectively forms the smaller particles. These smaller particles which were of similar sizes contribute to the low value of conductivity. When considering the sintering time, two temperatures were chosen for Cu MOD to better fit the temperatures suitable for PET (150 °C) and Kapton (300 °C) substrates. When liquid Cu MOD was sintered at 150 °C, an increase in the conductivity of the Cu conductor was observed with longer sintering times (from 100 to 700 kS/m). At 300 °C, the printed Cu conductor shows significantly higher conductivities (around 900 kS/m). These observations were expected because longer sintering times allow for better percolation and higher temperatures provide a higher conductivity at shorter sintering times. Interestingly, when sintering CuNi MOD, the sintering time at 300 °C did not seem to significantly affect the resulting conductivity with the values around 100 kS/m. This observation has a similar explanation for the CuNi sintering temperature. The average height of the CuNi prints tended to be higher compared to its Cu counterpart when evaluating using a profilometer (FIG. 9).

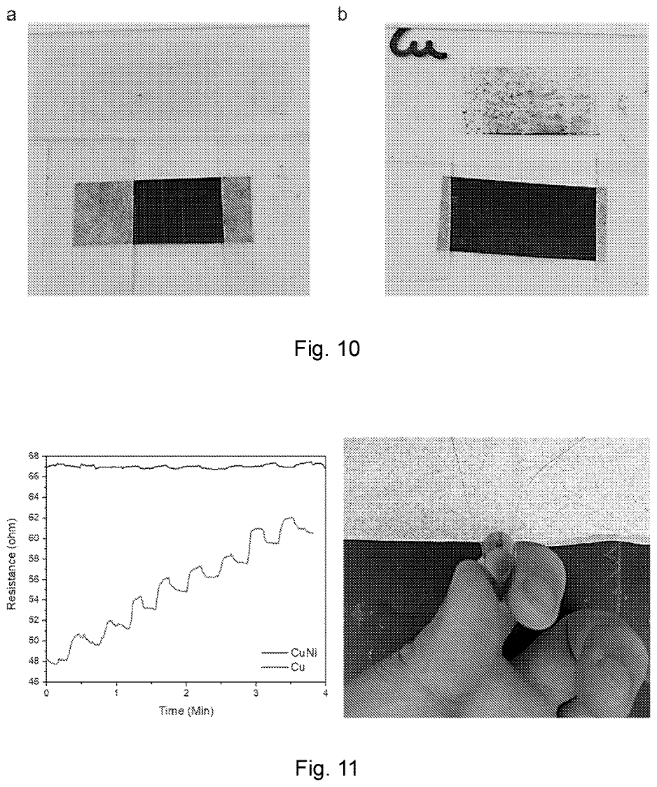

Under mechanical stress conditions (FIG. 3A), both printed Cu and CuNi conductors were stable with subtle resistance changes under the bent (o) and relaxed (x) conditions. Additionally, no discernable difference was observed once the cycling had been done. The current-voltage (I-V) curves were collected for Cu and CuNi under control (flat) and bent conditions (FIG. 3B). The curves for both Cu and CuNi were overlapped whether the sample was flat or bent, indicating good stability (given that the substrate length was 3.3 cm, the approximate bending radius was ~1 cm). Additionally, when evaluating the resistance change after every 10 cycles (FIG. 3B, inset), it was observed that there was essentially no change even after 100 cycles. This strongly supports that it is stable toward bending. Regarding adhesion, CuNi displayed a better adhesion on the Kapton substrate, with a rating of 5B, compared to pure Cu, which displayed a rating of 3B when subjected to scratch testing using a crosshatch cutter test kit (FIG. 10). Stability under humidity (~85% relative humidity) and elevated temperatures (~85 °C) was also tested. The control (under no stress) was first measured before heating and increasing the humidity. Under heat and humidity testing conditions (FIG. 3C), the CuNi was observed to be stable, and its resistance did not change throughout the test. Similarly, the printed Cu feature also showed no increase in resistance during the test. These observations show that when subjected to 85% humidity, CuNi and Cu traces printed as disclosed herein are stable. The stability under aging conditions (FIG. 3D) was evaluated at four temperatures (25, 50, 75, and 100 °C). Under all temperatures tested, both samples show steady responses throughout the aging (1 h), suggesting that they are stable under these conditions. These tests suggested the stability of printed Cu and CuNi features under different conditions. A protective layer was placed on top of the printed Cu—CuNi thermocouple using Kapton tape (FIG. 4A, inset), which provides additional protection to the conductors from the atmosphere.

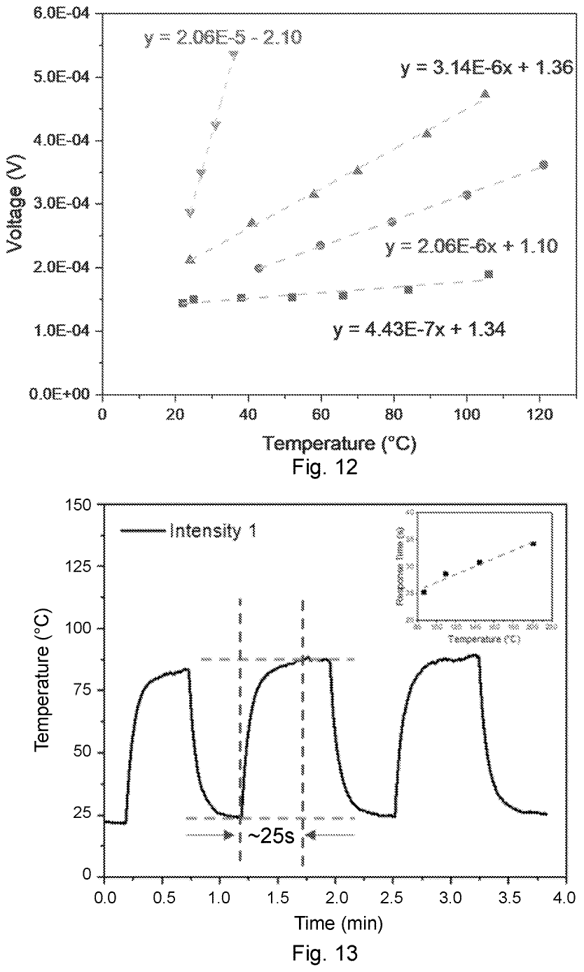

To determine the usability of a printed flexible Cu—CuNi thermocouple, a calibration curve of thermocouples was made to determine the performance. It was observed that depending on the initial resistance resulting from the varying thicknesses, the sensitivity of the thermocouple changed, shown from 0.4 to 20 μV/°C (FIG. 4A). This observed variance in sensitivity is a result of a difference in the thickness of printed Cu and CuNi conductors in the thermocouple. Thin-film materials show distinctive size effect, primarily the thickness of the thin film influencing the electrical characteristics of the thermocouple. And as the thickness of the junction falls in the micron range, its characteristics are heavily influenced by the thickness of the printed features. To derive maximum thermoelectric power, the printed feature thickness may be at least 250 nm. If ΔS_{Cu} and ΔS_{CuNi} represent the Seebeck coefficients of Cu and CuNi, respectively, then the sensitivity is given by S=ΔS_{Cu}−ΔS_{CuNi}, resulting in a sensitivity of 20.6 μV/°C. This allows for flexibility as the thermocouples can be modified by varying the jetting of the inks as per the requirements of a particular use. The heating performance collected for each thermocouple was shown to be fitted well to a linear line, which suggests its stable performance (FIG. 12). The printed Cu—CuNi type T thermocouple was then compared to a reference type T thermocouple detecting temperature in a box furnace (FIG. 4B). Clear differences can be seen when the thermocouples were held at different temperatures for 20 min. The printed thermocouples appear to have overshot the reading when compared to the reference type T thermocouple but is in very close agreement with the temperature output by the furnace temperature indicator via the in-built thermocouple (indicated by the Y-axis in the plot), which is likely due to the quick response time (vs reference thermocouple with a response time of 7 s in air) and the low thickness of the printed thermocouple (~2 μm). This indicates that the printed thermocouple was much faster and better in terms of response time and temperature indication, as the reference thermocouple was unable to quickly catch up to the furnace temperature. As can be seen during the holding time, the printed thermocouple reached the set temperature and began to show a drop in temperature during the idling state, whereas the reference type T thermocouple showed an inclining trend upward, indicating that it was still trying to reach the temperature set point. The reference thermocouple never managed to reach the temperature set point during the test, indicating that it needed longer holding time at each specific temperature. The response time of the thermocouple was also tested utilizing an ice cube (FIG. 4C) and body heat as temperature sources (FIG. 4D). With the ice cube, 10 cycles were conducted with the printed Cu—CuNi thermocouple showing consistent readings. Next, the thermocouple was cycled 10 times and was also shown to be consistent with a fast response time. To determine the response time, the graph was zoomed in and is shown in the inset of FIG. 4D. It was determined that the response time was around 2 s, from the start to where the reading plateaued. The printed Cu—CuNi thermocouple was also tested to determine viability on a contoured surface (FIG. 4E). The equation of linear fit can be utilized (y=mx+C or in this case, T=mV+C) where T and V represent the temperature and the voltage, respectively, m represents the slope, and C represents the intercept. Once the initial voltage is measured at room temperature, the slope can be utilized to determine the intercept by rearranging the linear fit equation, which can be utilized during recalibration. A control experiment was performed to evaluate the thermocouple under normal conditions. The sensitivity of the control sample was about 20.6 μV/°C with the data showing good fit to a linear line. When the sample was conformed to the shape of a hand, the sensitivity was practically unchanged (20.4 μV/°C), which further extends the reliability of the sensor under external stimuli such as bending in conformal settings. Lastly, the printed Cu—CuNi thermocouple was tested for stability during bending (FIG. 4D). A Cu—CuNi thermocouple was attached to a finger and subjected to bending. Three conditions are shown in FIG. 4D—relaxed, slightly bent, and largely bent—each separated by dashed lines. Although the starting voltage was lower, once the finger was bent, the thermocouple showed relatively stable readings. These observations show that the thermocouple is usable and has a linear heating curve, good response to heating, and good response time, with stable readings even after being contoured to a surface.

The table below compares thermocouples fabricated using different techniques, including ink-jetting according to embodiments of the present disclosure.

| | | Temperature | | |
|---|---|---|---|---|
| Material | Printing method | Range | Sensitivity | |
| In2O3/ITO | Screen Printing | 25 °C-1270 °C | 44.5 | μV/°C |
| Poly(3,4-ethylenedioxythio- | Screen Printing | −38 °C-77 °C | 10 | μV/K |
| phene):poly(4styrenesulfonate) | | | | |
| (PEDOT:PSS) and polyaniline | | | | |
| (PANI) | | | | |
| Carbon black and Silver | Screen Printing | 25 °C-150 °C | — | |
| Bismuth Tellurium (Bi2Te3) - | Screen Printing | 25 °C-80 °C | 262-282 | μV/K |
| Antimony Tellurium (Sb2Te3) | | | | |
| Graphene and Ti3C2Tx MXene | Aerosol Jetting | 30 °C-150 °C | 53.6 | μV/°C |
| Cu100Ni0—Cu48Ni52 | Direct-Writing | −5 °C to −65 °C | — | |
| Cu/CuNi | Reactive magnetron | 40 °C-180 °C | 45.23 | μV/°C |
| | sputtering | | | |
| PEDOT:PSS/Silver | Weldless direct ink | 25 °C-140 °C | 16.6-17 | μV/°C |
| | writing technique | | | |
| Carbon/Silver | Weldless direct ink | 25 °C-140 °C | 15-17.8 | μV/°C |
| | writing technique | | | |
| Cu/CuNi | Ink-jetting | 25 °C-100 °C | 20.6 | μV/°C |

Although the present disclosure has been described with respect to one or more particular embodiments, it will be understood that other embodiments of the present disclosure may be made without departing from the spirit and scope of the present disclosure. Hence, the present disclosure is deemed limited only by the appended claims and the reasonable interpretation thereof.

What is claimed is:

1. A method of making a thermocouple, the method comprising:
depositing a first metal organic decomposition ink on a substrate to form a first element;
depositing a second metal organic decomposition ink on the substrate to form a second element in electrical contact with the first element making a thermocouple junction;
sintering the first element; and
sintering the second elements.

2. The method of claim 1, wherein the first metal organic decomposition ink comprises a copper complex.

3. The method of claim 2, wherein the copper complex comprises an ionic copper center with two formate ligands and two amine ligands.

4. The method of claim 1, wherein the second metal-organic decomposition ink comprises a copper complex and a nickel complex.

5. The method of claim 4, wherein the copper complex comprises an ionic copper center with two formate ligands and two amine ligands, and the nickel complex comprises an ionic nickel center with two formate ligands and two amine ligands.

6. The method of claim 5, wherein sintering the second element causes a copper-nickel alloy to form in at least a portion of the second element.

7. The method of claim 1, wherein sintering the first element and sintering the second element are performed at sintering temperatures of between 100 °C to 400 °C, inclusive.

8. The method of claim 7, wherein the first element is sintered at a sintering temperature that is different from a sintering temperature of the second element.

9. The method of claim 1, wherein sintering the first element and sintering the second element are performed for sintering times of between 1 minute to 1 hour, inclusive.

10. The method of claim 9, wherein the first element is sintered for a sintering time that is different from a sintering time of the second element.

11. The method of claim 1, wherein the first element has a first Seebeck coefficient and the second element has a second Seebeck coefficient different from the first Seebeck coefficient such that the first and second elements cooperate to produce a thermocouple effect.

12. The method of claim 1, further comprising disposing a cover on the first element and the second element.

13. A thermocouple, comprising:
a substrate;
a first element printed on the substrate, the first element comprising a first metal-organic decomposition ink; and
a second element printed on the substrate and in electrical contact with the first element making a thermocouple junction, the second element comprising a second metal-organic decomposition ink.

14. The thermocouple of claim 13, wherein the first metal-organic decomposition ink comprises a copper complex.

15. The thermocouple of claim 14, wherein the copper complex comprises an ionic copper center with two formate ligands and two amine ligands.

16. The thermocouple of claim 13, wherein the second metal-organic decomposition ink comprises a copper complex and a nickel complex.

17. The thermocouple of claim 16, wherein the copper complex comprises an ionic copper center with two formate ligands and two amine ligands, and the nickel complex comprises an ionic nickel center with two formate ligands and two amine ligands.

18. The thermocouple of claim 13, wherein the first element has a first Seebeck coefficient and the second element has a second Seebeck coefficient different from the first Seebeck coefficient such that the first and second elements cooperate to produce a thermocouple effect.

19. A thermocouple, comprising:
a first element comprising sintered copper particles formed using a first metal organic decomposition ink;
a second element comprising sintered copper-nickel particles formed using a second metal organic decomposition ink;
wherein the first element has a Seebeck coefficient sufficiently different from a Seebeck coefficient of the second element such that the first and second elements produce a thermocouple effect.

20. A system for fabricating a thermocouple, the system comprising:
an inkjet printhead;
a first metal-organic decomposition ink which decomposes to a metal having a first Seebeck coefficient, the first metal-organic decomposition ink being in fluid communication with the inkjet printhead;
a second metal-organic decomposition ink which decomposes to a metal having a second Seebeck coefficient different from the first Seebeck coefficient, the second metal-organic decomposition ink being in fluid communication with the inkjet printhead.

21. The system of claim 20, wherein the inkjet printhead is configured to print sequentially using the first metal-organic decomposition ink and the second metal-organic decomposition ink.

22. The system of claim 20, wherein the inkjet printhead is configured to print simultaneously using the first metal-organic decomposition ink and the second metal-organic decomposition ink.
